(19) United States
(12) Patent Application Publication
(10) Pub. No.: US 2024/0421801 A1
(43) Pub. Date: Dec. 19, 2024

(54) METHOD AND APPARATUS FOR ESTIMATING FREQUENCY BAND OF RECEIVED SIGNAL, AND STORAGE MEDIUM STORING INSTRUCTIONS TO PERFORM METHOD FOR ESTIMATING FREQUENCY BAND OF RECEIVED SIGNAL

(71) Applicant: AGENCY FOR DEFENSE DEVELOPMENT, Daejeon (KR)

(72) Inventors: Jung Hoon LEE, Daejeon (KR); Seung Ho CHOI, Daejeon (KR); Je Il JO, Daejeon (KR)

(21) Appl. No.: 18/662,193

(22) Filed: May 13, 2024

(30) Foreign Application Priority Data
Jun. 15, 2023 (KR) 10-2023-0076823

(51) Int. Cl. H03H 17/02

(52) U.S. Cl. CPC H03H 17/0266; H03H 17/0202

(57) ABSTRACT

A method for estimating a frequency band of a received signal is proposed. The method may include acquiring the received signal using an antenna, and determining a first signal detection number corresponding to a first wideband filter for passing the received signal among a plurality of wideband filters which are respectively set with a plurality of pre-determined wideband frequencies included in a wideband filter bank. The method may also include determining a second signal detection number corresponding to a second narrowband filter for passing the received signal among a plurality of narrowband filters which are respectively set with a plurality of pre-determined narrowband frequencies included in a narrowband filter bank. The method may further include estimating the frequency band of the received signal based on at least one of the first signal detection number and the second signal detection number.

### CROSS-REFERENCE TO RELATED APPLICATION

This application claims priority to Korean Patent Application No. 10-2023-0076823 filed on Jun. 15, 2023. The entire contents of the application on which the priority is based are incorporated herein by reference.

### TECHNICAL FIELD

The present disclosure relates to a method and apparatus for estimating a frequency band for a received signal by detecting a video signal.

### BACKGROUND

Electronic warfare may be divided into an electronic support (ES) that detects and analyzes a radar transmission signal and an electronic attack (EA) that operates based on a detected result of ES. Since the EA is performed based on the ES, it is very important to detect and analyze the radar signal.

### SUMMARY

One aspect is a method for estimating a frequency band for a received signal using a first signal detection number and a second signal detection number determined by passing the received signal through a wideband filter bank and a narrowband filter bank.

The aspects of the present disclosure are not limited to the foregoing, and other aspects not mentioned herein will be clearly understood by those skilled in the art from the following description.

Another aspect is a method for estimating a frequency band of a received signal to be performed by an apparatus including a memory and a processor, for estimating a frequency band of a received signal including a memory and a processor the method comprises: acquiring the received signal using an antenna; determining a first signal detection number corresponding to a first wideband filter for passing the received signal among a plurality of wideband filters which are respectively set with a plurality of pre-determined wideband frequencies included in a wideband filter bank; determining a second signal detection number corresponding to a second narrowband filter for passing the received signal among a plurality of narrowband filters which are respectively set with a plurality of pre-determined narrowband frequencies included in a narrowband filter bank; and estimating the frequency band of the received signal based on at least one of the first signal detection number and the second signal detection number.

The determining the first signal detection number may include dividing a pre-determined frequency band into the plurality of pre-determined wideband frequencies using the wideband filter bank; determining an identification number of a first video detector for detecting the received signal passed through the first wideband filter among a plurality of wideband video detectors; and determining the determined identification number of the first video detector as the first signal detection number.

The determining the second signal detection number may include dividing the plurality of pre-determined wideband frequencies into the plurality of pre-determined narrowband frequencies using the narrowband filter bank; determining an identification number of a second video detector for detecting the received signal passed through the second narrowband filter among a plurality of narrowband video detectors; and determining the determined identification number of the second video detector as the second signal detection number.

The estimating the frequency band of the received signal may include estimating a wideband frequency band of the received signal using the first signal detection number.

The estimating the wideband frequency band of the received signal may include estimating the wideband frequency band based on calculations on a number of the divided wideband frequencies, a start frequency of the wideband frequencies, a width of the wideband frequencies, and the first signal detection number.

The estimating the frequency band of the received signal may include estimating a narrowband frequency band of the received signal using the second signal detection number.

The estimating the frequency band of the received signal may include estimating the narrowband frequency band based on calculations on a number of the divided narrowband frequencies, a start frequency of the narrowband frequencies, a width of the narrowband frequencies, and the second signal detection number.

Another aspect is an apparatus for estimating a frequency band of a received signal, the apparatus comprises: a memory storing one or more instructions; and a processor executing the one or more instructions stored in the memory, wherein the instructions, when executed by the processor, cause the processor to acquire the received signal using an antenna; determine a first signal detection number corresponding to a first wideband filter for passing the received signal among a plurality of wideband filters which are respectively set with a plurality of pre-determined wideband frequencies included in a wideband filter bank; determine a second signal detection number corresponding to a second narrowband filter for passing the received signal among a plurality of narrowband filters which are respectively set with a plurality of pre-determined narrowband frequencies included in a narrowband filter bank; and estimate the frequency band of the received signal based on at least one of the first signal detection number and the second signal detection number.

The processor may be configured to divide a pre-determined frequency band into the plurality of pre-determined wideband frequencies using the wideband filter bank, determine a identification number of a first video detector for detecting the received signal passed through the first wideband filter among a plurality of wideband video detectors, and determine the determined identification number of the first video detector as the first signal detection number.

The processor may be configured to divide the plurality of pre-determined wideband frequencies into the plurality of pre-determined narrowband frequencies using the narrowband filter bank, determine a identification number of a second video detector for detecting the received signal passed through the second narrowband filter among a plurality of narrowband video detectors; and determine the determined identification number of the second video detector as the second signal detection number.

The processor may be configured to estimate a wideband frequency band of the received signal using the first signal detection number.

The processor may be configured to estimate the wideband frequency band based on calculations on a number of the divided wideband frequencies, a start frequency of the wideband frequencies, a width of the wideband frequencies, and the first signal detection number.

The processor may be configured to estimate a narrowband frequency band of the received signal using the second signal detection number.

The processor may be configured to estimate the narrowband frequency band based on calculations on a number of the divided narrowband frequencies, a start frequency of the narrowband frequencies, a width of the narrowband frequencies, and the second signal detection number.

Another aspect is a non-transitory computer readable storage medium storing computer executable instructions, wherein the instructions, when executed by a processor, cause the processor to perform a method for estimating a frequency band of a received signal, the method comprising: acquiring the received signal using an antenna; determining a first signal detection number corresponding to a first wideband filter for passing the received signal among a plurality of wideband filters which are respectively set with a plurality of pre-determined wideband frequencies included in a wideband filter bank; determining a second signal detection number corresponding to a second narrowband filter for passing the received signal among a plurality of narrowband filters which are respectively set with a plurality of pre-determined narrowband frequencies included in a narrowband filter bank; and estimating the frequency band of the received signal based on at least one of the first signal detection number and the second signal detection number.

According to an embodiment of the present disclosure, as a frequency band of a received signal is estimated by dividing an entire frequency range into at least one first frequency band using a wideband filter bank and dividing each of the at least one first frequency band into at least one second frequency band using a narrowband filter bank, time delay can be minimized compared to a method of sequentially searching an entire band.

Further, according to an embodiment of the present disclosure, as a final frequency band of a received signal is estimated by performing a simple operation using a first signal detection number and a second signal detection number determined based on a number of a video detector that detects the received signal passing through a wideband filter bank and a narrowband filter bank, unnecessary costs are not incurred to improve hardware performance (e.g. size, weight, power consumption, etc.) in configuring the hardware of an electronic warfare receiver, thereby ensuring economic efficiency.

### BRIEF DESCRIPTION OF THE DRAWINGS

FIG. 1 is a block diagram showing an apparatus for estimating a frequency band according to an embodiment of the present disclosure.

FIG. 2 is a block diagram conceptually showing the function of a frequency-band estimation program according to an embodiment of the present disclosure.

FIG. 3 is a flowchart showing a method of estimating a frequency band according to an embodiment of the present disclosure.

FIG. 4 is a diagram illustrating the estimation of the frequency band of a received signal on the basis of a first signal detection number and a second signal detection number according to an embodiment of the present disclosure.

FIG. 5 is a diagram illustrating first frequency bands divided using a wideband filter bank and second frequency bands divided using a narrowband filter bank according to an embodiment of the present disclosure.

FIGS. 6 to 8 are diagrams illustrating the estimation of the frequency band with reference to a received signal according to an embodiment of the present disclosure.

### DETAILED DESCRIPTION

Generally, the ES detects the radar signal by searching a predefined frequency band (frequency domain of interest). At this time, since a receiving frequency domain of an electronic warfare system is tens of GHz, it may take a considerable time to detect an entire band. When detecting a target using a short-duration pulse, there is a problem in that it takes several seconds if a signal cycle is not correct.

That is, if the detection of a signal in the electronic warfare system is delayed by several seconds, an enemy attack would be recognized after it has already been executed, thereby making it difficult to take defensive measures. Likewise, military situations require quick tactical decision-making. However, if the detection of a signal is delayed by several seconds, this may make it difficult to make strategic decisions.

Therefore, there is a need to develop a method for estimating a frequency band of a received signal that can minimize time delay, instead of sequentially detecting signals by dividing an entire band into certain frequency intervals.

The advantages and features of the embodiments and the methods of accomplishing the embodiments will be clearly understood from the following description taken in conjunction with the accompanying drawings. However, embodiments are not limited to those embodiments described, as embodiments may be implemented in various forms. It should be noted that the present embodiments are provided to make a full disclosure and also to allow those skilled in the art to know the full range of the embodiments. Therefore, the embodiments are to be defined only by the scope of the appended claims.

Terms used in the present specification will be briefly described, and the present disclosure will be described in detail.

In terms used in the present disclosure, general terms currently as widely used as possible while considering functions in the present disclosure are used. However, the terms may vary according to the intention or precedent of a technician working in the field, the emergence of new technologies, and the like. In addition, in certain cases, there are terms arbitrarily selected by the applicant, and in this case, the meaning of the terms will be described in detail in the description of the corresponding invention. Therefore, the terms used in the present disclosure should be defined based on the meaning of the terms and the overall contents of the present disclosure, not just the name of the terms.

When it is described that a part in the overall specification “includes” a certain component, this means that other components may be further included instead of excluding other components unless specifically stated to the contrary.

In addition, a term such as a “unit” or a “portion” used in the specification means a software component or a hardware component such as FPGA or ASIC, and the “unit” or the “portion” performs a certain role. However, the “unit” or the “portion” is not limited to software or hardware. The “portion” or the “unit” may be configured to be in an addressable storage medium, or may be configured to reproduce one or more processors. Thus, as an example, the “unit” or the “portion” includes components (such as software components, object-oriented software components, class components, and task components), processes, functions, properties, procedures, subroutines, segments of program code, drivers, firmware, microcode, circuits, data, database, data structures, tables, arrays, and variables. The functions provided in the components and “unit” may be combined into a smaller number of components and “units” or may be further divided into additional components and “units”.

Hereinafter, the embodiment of the present disclosure will be described in detail with reference to the accompanying drawings so that those of ordinary skill in the art may easily implement the present disclosure. In the drawings, portions not related to the description are omitted in order to clearly describe the present disclosure.

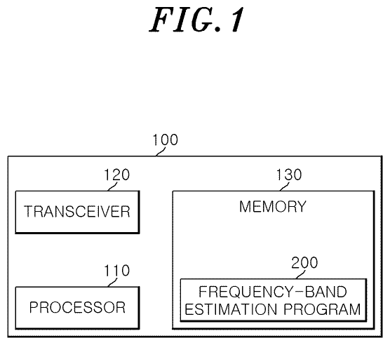

FIG. 1 is a block diagram showing an apparatus for estimating a frequency band according to an embodiment of the present disclosure.

Referring to FIG. 1, the apparatus 100 for estimating the frequency band may include a processor 110, a transceiver 120, and a memory 130.

The processor 110 may control the overall operation of the frequency band estimating apparatus 100.

The processor 110 may obtain a received signal using the transceiver 120.

Specifically, the processor 110 may obtain the received signal from an antenna using the transceiver 120.

Although it has been described in the present disclosure that the received signal is received through the transceiver 120, the present disclosure is not limited thereto. That is, according to an embodiment, the frequency band estimating apparatus 100 may include an input/output device (not shown), and the frequency band estimating apparatus 100 may acquire the received signal using the input/output device (not shown). The received signal may be generated in the frequency band estimating apparatus 100.

In this context, the received signal may refer to a signal obtained by receiving a transmission signal of a radar (e.g. target radar).

The processor 110 may acquire the received signal using the antenna, pass the received signal through a wideband filter bank to determine a first signal detection number, pass the received signal through a narrowband filter bank to determine a second signal detection number, and estimate the frequency band of the received signal on the basis of at least one of the first signal detection number and the second signal detection number.

In the present disclosure, the wideband filter bank may include a distributor that branches a received signal, a band-pass filter that passes the received signal through a frequency corresponding to a divided first frequency band, a video detector that detects the passing received signal, a frequency mixer that reduces the received signal to the frequency of the narrowband filter bank, and a coupler that couples signals passing through the band-pass filter.

In the present disclosure, the narrowband filter bank may include a distributor that branches a received signal, a band-pass filter that passes the received signal through a frequency corresponding to a divided second frequency band, a video detector that detects the passing received signal, a switch that performs an on/off function for the passing received signal, and a coupler that couples signals passing through the band-pass filter.

The memory 130 may include a frequency-band estimation program 200 and information required for executing the frequency-band estimation program 200.

Herein, the frequency-band estimation program 200 may mean software including instructions that acquire a received signal and then estimate the frequency band of the received signal, on the basis of at least one of the first signal detection number and the second signal detection number.

The processor 110 may load the frequency-band estimation program 200 and information required for executing the frequency-band estimation program 200 from the memory 130 so as to execute the frequency-band estimation program 200.

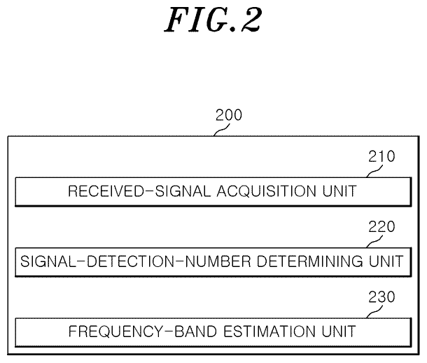

The function and/or operation of the frequency-band estimation program 200 will be described in detail with reference to FIG. 2.

FIG. 2 is a block diagram conceptually showing the function of a frequency-band estimation program according to an embodiment of the present disclosure.

Referring to FIG. 2, the frequency-band estimation program 200 may include a received-signal acquisition part (or a received-signal acquisition processor) 210, a signal-detection-number determining part (or a signal-detection-number determining processor) 220, and a frequency-band estimation part (or a frequency-band estimation processor) 230.

The received-signal acquisition part 210, the signal-detection-number determining part 220, and the frequency-band estimation part 230 shown in FIG. 2 conceptually divide the function of the frequency-band estimation program 200 so as to easily explain the function of the frequency-band estimation program 200, but the present disclosure is not limited thereto. According to embodiments, the functions of the received-signal acquisition part 210, the signal-detection-number determining part 220, and the frequency-band estimation part 230 may be merged/separated, and may be implemented as a series of instructions included in one program.

First, the received-signal acquisition part 210 may acquire the received signal using the antenna.

Specifically, the received-signal acquisition part 210 may acquire the received signal using the antenna, and the acquired received signal may be branched into the wideband filter bank using the distributor.

Next, the signal-detection-number determining part 220 may determine the first signal detection number by causing the received signal to pass through the wideband filter bank.

Specifically, the signal-detection-number determining part 220 may divide a predetermined frequency band into at least one first frequency band using the wideband filter bank.

For example, when the predetermined frequency band (e.g. an entire received frequency range) is in a range of 0 GHz to 80 GHz, the signal-detection-number determining part 220 may use the wideband filter bank to divide the predetermined frequency band into a 1-1 frequency band corresponding to 0 GHz to 20 GHz, a 1-2 frequency band corresponding to 20 GHz to 40 GHz, a 1-3 frequency band corresponding to 40 GHz to 60 GHz, and a 1-4 frequency band corresponding to 60 GHz to 80 GHz.

Further, the signal-detection-number determining part 220 may determine the number of the first video detector that detects the passing received signal among at least one first video detector corresponding to at least one first frequency band, as the first signal detection number.

For example, at least one first video detector may include a 1-1 video detector corresponding to the 1-1 frequency band, a 1-2 video detector corresponding to the 1-2 frequency band, a 1-3 video detector corresponding to the 1-3 frequency band, and a 1-4 video detector corresponding to the 1-4 frequency band. When the received signal passes through the wideband filter bank and the passing received signal is detected by the 1-3 video detector, the signal-detection-number determining part 220 may determine the number of the 1-3 video detector as the first signal detection number.

Further, the signal-detection-number determining part 220 may divide at least one first frequency band into a second frequency band using the narrowband filter bank.

For example, the signal-detection-number determining part 220 may use the narrowband filter bank to divide the 1-1 frequency band corresponding to 0 GHz to 20 GHZ into a 2-1 frequency band corresponding to 0 GHz to 2.5 GHZ, a 2-2 frequency band corresponding to 2.5 GHz to 5 GHZ, a 2-3 frequency band corresponding to 5 GHz to 7.5 GHZ, a 2-4 frequency band corresponding to 7.5 GHz to 10 GHZ, a 2-5 frequency band corresponding to 10 GHz to 12.5 GHZ, a 2-6 frequency band corresponding to 12.5 GHz to 15 GHz, a 2-7 frequency band corresponding to 15 GHz to 17.5 GHZ, and a 2-8 frequency band corresponding to 17.5 GHz to 20 GHz.

Likewise, the signal-detection-number determining part 220 may use the narrowband filter bank to divide each of the 1-2 frequency band to the 1-4 frequency band into the 2-1 frequency band to the 2-8 frequency band.

Further, the signal-detection-number determining part 220 may determine the number of the second video detector that detects the passing received signal among at least one second detector corresponding to at least one second frequency band, as the second signal detection number.

For example, at least one second video detector may include a 2-1 video detector corresponding to the 2-1 frequency band, a 2-2 video detector corresponding to the 2-2 frequency band, a 2-3 video detector corresponding to the 2-3 frequency band, a 2-4 video detector corresponding to the 2-4 frequency band, a 2-5 video detector corresponding to the 2-5 frequency band, a 2-6 video detector corresponding to the 2-6 frequency band, a 2-7 video detector corresponding to the 2-7 frequency band, and a 2-8 video detector corresponding to the 2-8 frequency band. When the received signal passes through the narrowband filter bank and the passing received signal is detected by the 2-7 video detector, the signal-detection-number determining part 220 may determine the number of the 2-7 video detector as the second signal detection number.

However, the number of the divided first frequency bands and the number of the divided second frequency bands according to an embodiment of the present disclosure are merely illustrative, and may be changed in various ways within the scope of achieving the purpose of the present disclosure.

Next, the frequency-band estimation part 230 may estimate the frequency band of the received signal, on the basis of at least one of the first signal detection number and the second signal detection number.

Specifically, the frequency-band estimation part 230 may estimate the wideband frequency band of the received signal.

To be more specific, the frequency-band estimation part 230 may estimate the wideband frequency band, on the basis of calculations on the number of the divided first frequency bands, the start frequency of the first frequency band, the width of the first frequency band, and the first signal detection number.

For example, the wideband frequency band of the estimated received signal may be expressed as the following Equation 1.

$${f}_{w} \frac{wBW}{N} ( k - 1 ) < {f}_{1} \leq {f}_{w} + \frac{wBW}{N} ( k ) \qquad Equation 1$$

Here, f_{w} may represent the start frequency of the first frequency band, wBW may represent the width of the first frequency band, k may represent the first signal detection number, N may represent the number of divided first frequency bands, and f₁ may represent the wideband frequency.

Further, the frequency-band estimation part 230 may estimate the narrowband frequency band of the received signal.

To be more specific, the frequency-band estimation part 230 may estimate the narrowband frequency band, on the basis of calculations on the number of the divided second frequency bands, the start frequency of the second frequency band, the width of the second frequency band, and the second signal detection number.

For example, the narrowband frequency band of the estimated received signal may be expressed as the following Equation 2.

$${f}_{n} \frac{nBW}{n} ( r - 1 ) < {f}_{2} \leq {f}_{n} + \frac{nBW}{n} ( r ) \qquad Equation 2$$

Here, fₙ may mean the start frequency of the second frequency band, nBW may mean the width of the second frequency band, r may mean the second signal detection number, n may mean the number of divided second frequency bands, and f₂ may mean the narrowband frequency.

Further, the frequency-band estimation part 230 may estimate a final frequency band of the received signal, using the first signal detection number and the second signal detection number.

For example, the estimated frequency band may be expressed as the following Equation 3.

$${f}_{n} + ( k - 1 ) \cdot \frac{wBW}{N} + \frac{nBW}{n} ( r - 1 ) < f \leq {f}_{n} + ( k - 1 ) \cdot \frac{wBW}{N} + \frac{nBW}{n} ( r ) \qquad Equation 3$$

Here, fₙ may mean the start frequency of the second frequency band, wBW may mean the width of the first frequency band, k may mean the first signal detection number, N may mean the number of divided first frequency bands, nBW may mean the width of the second frequency band, r may mean the second signal detection number, n may mean the number of divided second frequency bands, and f may mean the final frequency of the received signal.

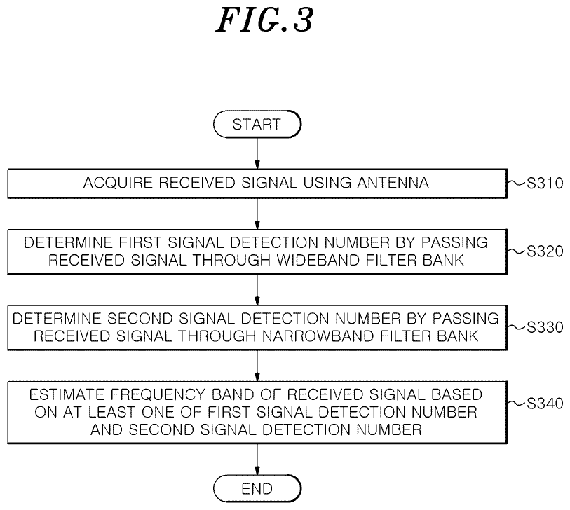

FIG. 3 is a flowchart showing a method of estimating a frequency band according to an embodiment of the present disclosure.

Referring to FIGS. 2 and 3, the received-signal acquisition part 210 may acquire the received signal using the antenna (S310).

The signal-detection-number determining part 220 may determine the first signal detection number by passing the received signal through the wideband filter bank (S320).

The signal-detection-number determining part 220 may determine the second signal detection number by passing the received signal through the narrowband filter bank (S330).

The frequency-band estimation part 230 may estimate the frequency band of the received signal, on the basis of at least one of the first signal detection number and the second signal detection number (S340).

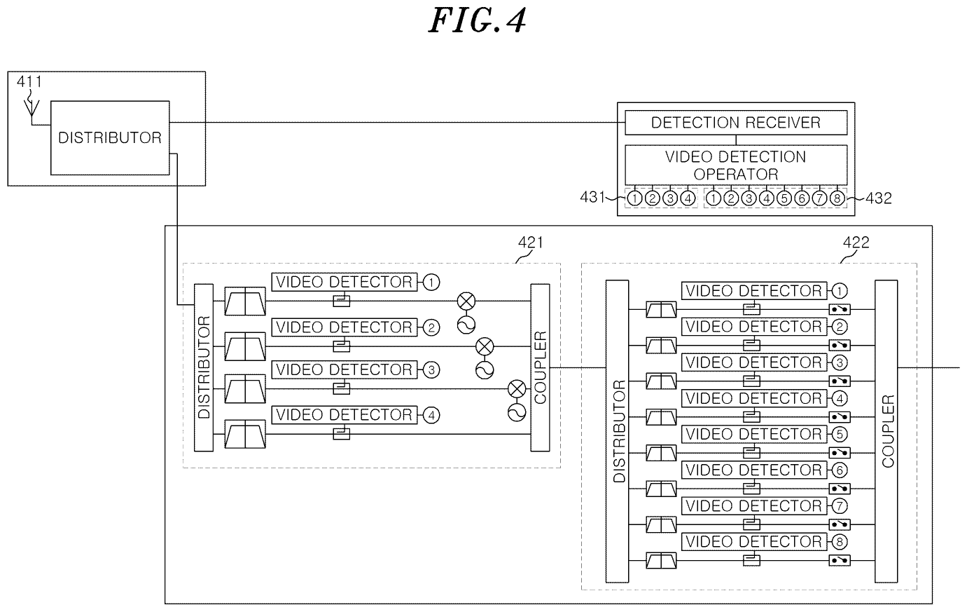

FIG. 4 is a diagram illustrating the estimation of the frequency band of a received signal on the basis of a first signal detection number and a second signal detection number according to an embodiment of the present disclosure.

Referring to FIGS. 2 and 4, the received-signal acquisition part 210 may acquire a received signal using an antenna 411, and the received signal may be branched through a distributor and then be transmitted to a wideband filter bank 421 and a detection receiver.

Next, when the signal-detection-number determining part 220 passes the received signal through the wideband filter bank 421, a signal that has passed through the band-pass filter of the wideband filter bank 421 may be detected through one of the first video detectors from the 1-1 video detector to the 1-4 video detector. The signal-detection-number determining part 220 may determine the number (i.e., \textcircled{1}) of the 1-1 video detector that detects the received signal as a first signal detection number 431 that is input into a video detection operator.

Further, when the signal-detection-number determining part 220 passes the received signal through a narrowband filter bank 422, a signal that has passed through the band-pass filter of the narrowband filter bank 422 may be detected through one of the second video detectors from the 2-1 video detector to the 2-8 video detector. The signal-detection-number determining part 220 may determine the number (i.e., \textcircled{8}) of the 2-8 video detector that detects the received signal as a second signal detection number 432 that is input into the video detection operator.

Next, the frequency-band estimation part 230 may estimate a final frequency band of the received signal using the first signal detection number 431 and the second signal detection number 432 that are input into the video detection operator.

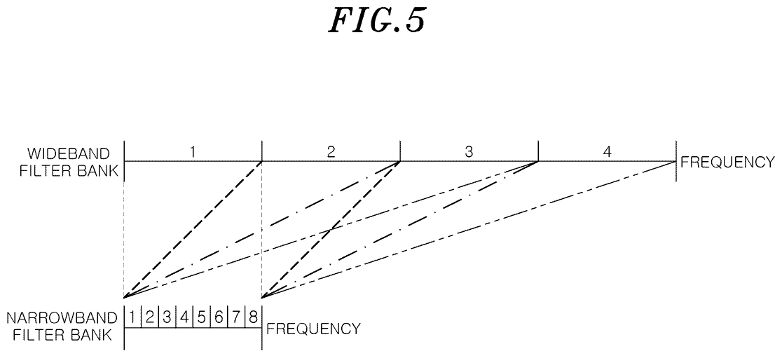

FIG. 5 is a diagram illustrating first frequency bands divided using a wideband filter bank and second frequency bands divided using a narrowband filter bank according to an embodiment of the present disclosure.

Referring to FIGS. 2 and 5, the signal-detection-number determining part 220 may divide the predetermined frequency band into four first frequency bands using the wideband filter bank, and the received signal may be detected by the first video detector corresponding to the four divided first frequency bands.

For example, the number of the 1-1 video detector corresponding to the 1-1 frequency band may be 1, the number of the 1-2 video detector corresponding to the 1-2 frequency band may be 2, the number of the 1-3 video detector corresponding to the 1-3 frequency band may be 3, and the number of the 1-4 video detector corresponding to the 1-4 frequency band may be 4.

Further, the signal-detection-number determining part 220 may divide each of the four first frequency bands into eight second frequency bands using the narrowband filter bank, and the received signal may be detected by the second video detector corresponding to the eight divided second frequency bands.

For example, the number of the 2-1 video detector corresponding to the 2-1 frequency band may be 1, the number of the 2-2 video detector corresponding to the 2-2 frequency band may be 2, the number of the 2-3 video detector corresponding to the 2-3 frequency band may be 3, the number of the 2-4 video detector corresponding to the 2-4 frequency band may be 4, the number of the 2-5 video detector corresponding to the 2-5 frequency band may be 5, the number of the 2-6 video detector corresponding to the 2-6 frequency band may be 6, the number of the 2-7 video detector corresponding to the 2-7 frequency band may be 7, and the number of the 2-8 video detector corresponding to the 2-8 frequency band may be 8. The same applies to distinguish the 1-1 frequency band to the 1-4 frequency band.

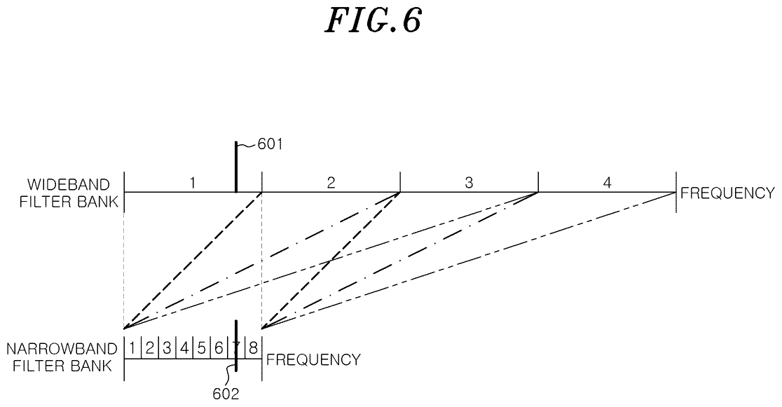

FIGS. 6 to 8 are diagrams illustrating the estimation of the frequency band with reference to a received signal according to an embodiment of the present disclosure.

First, referring to FIGS. 2 and 6, when the frequency of the received signal is 7.1 GHZ, the signal-detection-number determining part 220 may determine a first signal detection number 601 as 1, and determine a second signal detection number 602 as 7. The frequency-band estimation part 230 may estimate a final frequency band using the first signal detection number 601 and the second signal detection number 602.

For example, when an entire receiving frequency range is from 4 GHz to 20 GHz and the number of divided first frequency bands is 4, the frequency-band estimation part 230 may estimate the wideband frequency band of the received signal from 4 GHz to 8 GHZ because the width of the first frequency band is 4 GHz and the first signal detection number 601 is 1.

Next, when the number of divided second frequency bands is 8, the frequency-band estimation part 230 may estimate the narrowband frequency band of the received signal from 7 GHz to 7.5 GHz because the width of the second frequency band is 0.5 GHz and the second signal detection number 602 is 7.

Therefore, the frequency-band estimation part 230 may estimate the final frequency band of the received signal from 7 GHz to 7.5 GHZ, and it can be confirmed that the final frequency band is appropriately estimated, considering that the frequency of the received signal is 7.1 GHZ.

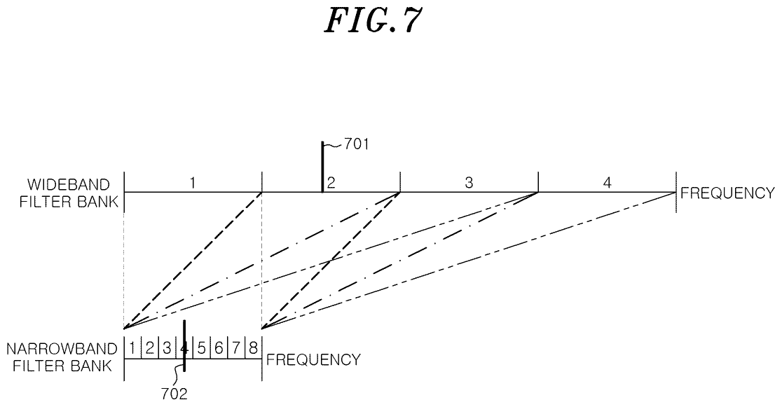

Next, referring to FIGS. 2 and 7, when the frequency of the received signal is 9.9 GHZ, the signal-detection-number determining part 220 may determine a first signal detection number 701 as 2, and determine a second signal detection number 702 as 4. The frequency-band estimation part 230 may estimate a final frequency band using the first signal detection number 701 and the second signal detection number 702.

For example, since an entire receiving frequency range is from 4 GHz to 20 GHz, the number of divided first frequency bands is 4, the width of the first frequency band is 4 GHZ, the first signal detection number 701 is 2, the number of divided second frequency bands is 8, the width of the second frequency band is 0.5 GHZ, and the second signal detection number 702 is 4, the frequency-band estimation part 230 may estimate the narrowband frequency band of the received signal from 9.5 GHz to 10 GHZ.

Therefore, the frequency-band estimation part 230 may estimate the final frequency band of the received signal from 9.5 GHz to 10 GHz, and it can be confirmed that the final frequency band is appropriately estimated, considering that the frequency of the received signal is 9.9 GHZ.

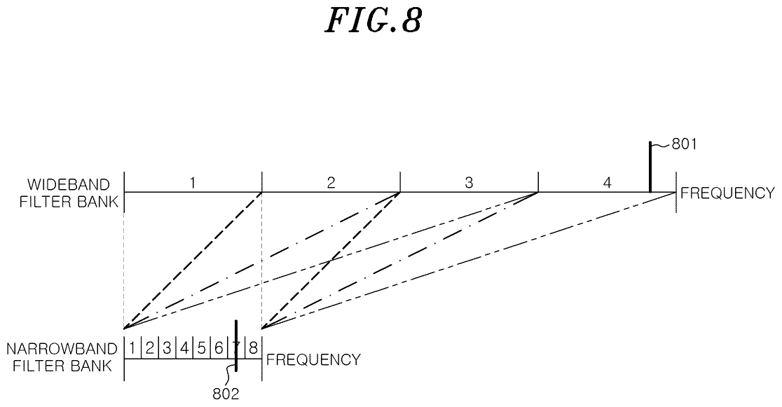

Next, referring to FIGS. 2 and 8, when the frequency of the received signal is 19.4 GHz, the signal-detection-number determining part 220 may determine a first signal detection number 801 as 4, and determine a second signal detection number 802 as 7. The frequency-band estimation part 230 may estimate a final frequency band using the first signal detection number 801 and the second signal detection number 802.

For example, since an entire receiving frequency range is from 4 GHz to 20 GHz, the number of divided first frequency bands is 4, the width of the first frequency band is 4 GHz, the first signal detection number 801 is 4, the number of divided second frequency bands is 8, the width of the second frequency band is 0.5 GHZ, and the second signal detection number 802 is 7, the frequency-band estimation part 230 may estimate the narrowband frequency band of the received signal from 19 GHz to 19.5 GHZ.

Therefore, the frequency-band estimation part 230 may estimate the final frequency band of the received signal from 19 GHz to 19.5 GHZ, and it can be confirmed that the final frequency band is appropriately estimated, considering that the frequency of the received signal is 19.4 GHZ.

Combinations of steps in each flowchart attached to the present disclosure may be executed by computer program instructions. Since the computer program instructions can be mounted on a processor of a general-purpose computer, a special purpose computer, or other programmable data processing equipment, the instructions executed by the processor of the computer or other programmable data processing equipment create a means for performing the functions described in each step of the flowchart. The computer program instructions can also be stored on a computer-usable or computer-readable storage medium which can be directed to a computer or other programmable data processing equipment to implement a function in a specific manner. Accordingly, the instructions stored on the computer-usable or computer-readable recording medium can also produce an article of manufacture containing an instruction means which performs the functions described in each step of the flowchart. The computer program instructions can also be mounted on a computer or other programmable data processing equipment. Accordingly, a series of operational steps are performed on a computer or other programmable data processing equipment to create a computer-executable process, and it is also possible for instructions to perform a computer or other programmable data processing equipment to provide steps for performing the functions described in each step of the flowchart.

In addition, each step may represent a module, a segment, or a portion of codes which contains one or more executable instructions for executing the specified logical function(s). It should also be noted that in some alternative embodiments, the functions mentioned in the steps may occur out of order. For example, two steps illustrated in succession may in fact be performed substantially simultaneously, or the steps may sometimes be performed in a reverse order depending on the corresponding function.

The above description is merely exemplary description of the technical scope of the present disclosure, and it will be understood by those skilled in the art that various changes and modifications can be made without departing from original characteristics of the present disclosure. Therefore, the embodiments disclosed in the present disclosure are intended to explain, not to limit, the technical scope of the present disclosure, and the technical scope of the present disclosure is not limited by the embodiments. The protection scope of the present disclosure should be interpreted based on the following claims and it should be appreciated that all technical scopes included within a range equivalent thereto are included in the protection scope of the present disclosure.

What is claimed is:

1. A method for estimating a frequency band of a received signal to be performed by an apparatus including a memory and a processor, for estimating a frequency band of a received signal including a memory and a processor, the method comprising:
acquiring the received signal using an antenna;
determining a first signal detection number corresponding to a first wideband filter for passing the received signal among a plurality of wideband filters which are respectively set with a plurality of pre-determined wideband frequencies included in a wideband filter bank;
determining a second signal detection number corresponding to a second narrowband filter for passing the received signal among a plurality of narrowband filters which are respectively set with a plurality of pre-determined narrowband frequencies included in a narrowband filter bank; and
estimating the frequency band of the received signal based on at least one of the first signal detection number and the second signal detection number.

2. The method of claim 1, wherein determining the first signal detection number includes:
dividing a pre-determined frequency band into the plurality of pre-determined wideband frequencies using the wideband filter bank; determining an identification number of a first video detector for detecting the received signal passed through the first wideband filter among a plurality of wideband video detectors; and
determining the determined identification number of the first video detector as the first signal detection number.

3. The method of claim 2, wherein determining the second signal detection number includes:
dividing the plurality of pre-determined wideband frequencies into the plurality of pre-determined narrowband frequencies using the narrowband filter bank;
determining an identification number of a second video detector for detecting the received signal passed through the second narrowband filter among a plurality of narrowband video detectors; and
determining the determined identification number of the second video detector as the second signal detection number.

4. The method of claim 2, wherein estimating the frequency band of the received signal includes:
estimating a wideband frequency band of the received signal using the first signal detection number.

5. The method of claim 4, wherein estimating the wideband frequency band of the received signal includes:
estimating the wideband frequency band based on calculations on a number of the divided wideband frequencies, a start frequency of the wideband frequencies, a width of the wideband frequencies, and the first signal detection number.

6. The method of claim 3, wherein estimating the frequency band of the received signal includes:
estimating a narrowband frequency band of the received signal using the second signal detection number.

7. The method of claim 6, wherein estimating the narrowband frequency band of the received signal includes:
estimating the narrowband frequency band based on calculations on a number of the divided narrowband frequencies, a start frequency of the narrowband frequencies, a width of the narrowband frequencies, and the second signal detection number.

8. An apparatus for estimating a frequency band of a received signal, the apparatus comprising:
a memory storing one or more instructions; and
one or more processors executing the one or more instructions to
acquire the received signal using an antenna;
determine a first signal detection number corresponding to a first wideband filter for passing the received signal among a plurality of wideband filters which are respectively set with a plurality of pre-determined wideband frequencies included in a wideband filter bank;
determine a second signal detection number corresponding to a second narrowband filter for passing the received signal among a plurality of narrowband filters which are respectively set with a plurality of pre-determined narrowband frequencies included in a narrowband filter bank; and
estimate the frequency band of the received signal based on at least one of the first signal detection number and the second signal detection number.

9. The apparatus of claim 8, wherein at least one of the one or more processors is configured to divide a pre-determined frequency band into the plurality of pre-determined wideband frequencies using the wideband filter bank, determine a identification number of a first video detector for detecting the received signal passed through the first wideband filter among a plurality of wideband video detectors, and determine the determined identification number of the first video detector as the first signal detection number.

10. The apparatus of claim 9, wherein at least one of the one or more processors is configured to divide the plurality of pre-determined wideband frequencies into the plurality of pre-determined narrowband frequencies using the narrowband filter bank, determine a identification number of a second video detector for detecting the received signal passed through the second narrowband filter among a plurality of narrowband video detectors; and determine the determined identification number of the second video detector as the second signal detection number.

11. The apparatus of claim 9, wherein at least one of the one or more processors is configured to estimate a wideband frequency band of the received signal using the first signal detection number.

12. The apparatus of claim 11, wherein at least one of the one or more processors is configured to estimate the wideband frequency band based on calculations on a number of the divided wideband frequencies, a start frequency of the wideband frequencies, a width of the wideband frequencies, and the first signal detection number.

13. The apparatus of claim 10, wherein at least one of the one or more processors is configured to estimate a narrowband frequency band of the received signal using the second signal detection number.

14. The apparatus of claim 13, wherein at least one of the one or more processors is configured to estimate the narrowband frequency band based on calculations on a number of the divided narrowband frequencies, a start frequency of the narrowband frequencies, a width of the narrowband frequencies, and the second signal detection number.

15. A non-transitory computer readable storage medium storing computer executable instructions, wherein the instructions, when executed by one or more processors, cause the one or more processors to perform the method of claim 1.
